(19) United States
(12) Patent Application Publication
(10) Pub. No.: US 2026/0223473 A1
(43) Pub. Date: Jul. 30, 2026

(54) SOLID-STATE IMAGING DEVICE

(71) Applicant: SONY SEMICONDUCTOR SOLUTIONS CORPORATION, KANAGAWA (JP)

(72) Inventor: MASAKI HANEDA, KANAGAWA (JP)

(21) Appl. No.: 19/149,163

(22) PCT Filed: Jan. 9, 2024
(86) PCT No.: PCT/JP2024/000095

§ 371 Date: Jul. 18, 2025

(30) Foreign Application Priority Data
Jan. 27, 2023 (JP) 2023-010910

(51) Int. Cl. H10F 39/00; H04N 25/79

(52) U.S. Cl. CPC H10F 39/809; H04N 25/79; H10F 39/811

(57) ABSTRACT

A solid-state imaging device includes: a first base including a photoelectric conversion element that converts light into electric charge; a second base including a first signal processing circuit that performs signal processing on a basis of the electric charge obtained through conversion performed by the photoelectric conversion element and being different from the first base; and a third base including a protection element that is electrically coupled to the first signal processing circuit and absorbs an overcurrent and being different from the first base and the second base.

### TECHNICAL FIELD

The present disclosure relates to a solid-state imaging device.

### BACKGROUND ART

PTL 1 discloses a photoelectric conversion device. In the photoelectric conversion device, a plurality of substrates including a first substrate, a second substrate, and a third substrate is stacked.

The first substrate includes a plurality of photoelectric conversion sections. The second substrate includes a plurality of pixel circuits in a manner corresponding to the photoelectric conversion sections. The third substrate includes a signal processing circuit that processes signals outputted from the pixel circuits.

### CITATION LIST

### Patent Literature

PTL 1: Japanese Unexamined Patent Application Publication No. 2022-113123

### SUMMARY OF THE INVENTION

With the photoelectric conversion device disclosed in PTL 1 described above, for example, a protection circuit that provides protection from electrostatic breakdown is required during manufacture or after production completion. The protection circuit is formed for each of the first substrate, the second substrate, and the third substrate. For example, upon manufacturing the first substrate as a plurality of semiconductor chips from one semiconductor wafer, a plurality of protection circuits is formed in a manner corresponding to the respective first substrates. That is, the number of first substrates that are obtainable from one semiconductor wafer decreases in a manner corresponding to the number of protection circuits. Thus, there have been demands on increasing the number of substrates that are obtainable from a semiconductor wafer.

A solid-state imaging device according to a first embodiment of the present disclosure includes: a first base including a photoelectric conversion element that converts light into electric charge; a second base including a first signal processing circuit that performs signal processing on a basis of the electric charge obtained through conversion performed by the photoelectric conversion element and being different from the first base; and a third base including a protection element that is electrically coupled to the first signal processing circuit and absorbs an overcurrent and being different from the first base and the second base.

In a solid-state imaging device according to a second embodiment of the present disclosure, each of the second base and the third base is stacked on the first base in the solid-state imaging device according to the first embodiment.

In a solid-state imaging device according to a third embodiment of the present disclosure, the protection element includes a diode in the solid-state imaging device according to the first embodiment or the second embodiment.

### BRIEF DESCRIPTION OF THE DRAWINGS

FIG. 1 is a vertical cross-sectional configuration diagram of main parts of a solid-state imaging device according to a first embodiment of the present disclosure.

FIG. 2 is a block diagram of a system loaded in the solid-state imaging device illustrated in FIG. 1.

FIG. 3 is a schematic perspective plan view of the solid-state imaging device illustrated in FIG. 1.

FIG. 4 is a cross-sectional view of a first process individually illustrated from processes of a method for manufacturing the solid-state imaging device according to the first embodiment.

FIG. 5 is a cross-sectional view of a second process.

FIG. 6 is a cross-sectional view of a third process.

FIG. 7 is a cross-sectional view of a fourth process.

FIG. 8 is a cross-sectional view of a fifth process.

FIG. 9 is a cross-sectional view of a sixth process.

FIG. 10 is a cross-sectional view of a seventh process.

FIG. 11 is a cross-sectional view of an eighth process.

FIG. 12 is a cross-sectional view of a ninth process.

FIG. 13 is a cross-sectional view of a tenth process.

FIG. 14 is a cross-sectional view of an eleventh process.

FIG. 15 is a cross-sectional view of a twelfth process.

FIG. 16 is a cross-sectional view of a thirteenth process.

FIG. 17 is a cross-sectional view of a fourteenth process.

FIG. 18 is an enlarged vertical cross-sectional configuration diagram of main parts of a solid-state imaging device according to a second embodiment of the present disclosure.

FIG. 19 is a perspective plan view, corresponding to FIG. 3, of a solid-state imaging device according to a third embodiment of the present disclosure.

FIG. 20 is a perspective plan view, corresponding to FIG. 18, of a solid-state imaging device according to a modification example of the third embodiment.

FIG. 21 is a vertical cross-sectional configuration diagram, corresponding to FIG. 1, of a solid-state imaging device according to a fourth embodiment of the present disclosure.

FIG. 22 is a vertical cross-sectional configuration diagram, corresponding to FIG. 1, of a solid-state imaging device according to a fifth embodiment of the present disclosure.

FIG. 23 is a vertical cross-sectional configuration diagram, corresponding to FIG. 1, of a solid-state imaging device according to a sixth embodiment of the present disclosure.

FIG. 24 is a vertical cross-sectional configuration diagram, corresponding to FIG. 1, of a solid-state imaging device according to a seventh embodiment of the present disclosure.

FIG. 25 is a vertical cross-sectional configuration diagram, corresponding to FIG. 1, of a solid-state imaging device according to an eighth embodiment of the present disclosure.

FIG. 26 is a block diagram depicting an example of schematic configuration of a vehicle control system.

FIG. 27 is a diagram of assistance in explaining an example of installation positions of an outside-vehicle information detecting section and an imaging section.

FIG. 28 is a view depicting an example of a schematic configuration of an endoscopic surgery system.

FIG. 29 is a block diagram depicting an example of a functional configuration of a camera head and a camera control unit (CCU).

### MODES FOR CARRYING OUT THE INVENTION

Hereinafter, embodiments of the present disclosure will be described in detail with reference to the drawings. It is to be noted that description is given in the following order.

### 1. First Embodiment

Illustrated in the first embodiment is a first example where the present technology is applied to a solid-state imaging device. As the solid-state imaging device, a back-illuminated solid-state imaging device is built in the first embodiment. Note that it is also possible to build a front-illuminated imaging device as the solid-state imaging device. Moreover, a system configuration, a vertical cross-sectional configuration, and a manufacturing method of the solid-state imaging device will be described in the first embodiment.

### 2. Second Embodiment

The second embodiment is a second example obtained by changing a structure of an electrode of a protection element in the solid-state imaging device according to the first embodiment.

### 3. Third Embodiment

The third embodiment is a third example illustrating a basic stacking layout in the solid-state imaging device according to the first embodiment. A modification example is also illustrated in the third embodiment.

### 4. Fourth Embodiment

The fourth embodiment is a fourth example obtained by changing a structure of coupling between the protection element and an external terminal in the solid-state imaging device according to the first embodiment.

### 5. Fifth Embodiment

The fifth embodiment is a fifth example obtained by changing the structure of the coupling between the protection element and the external terminal in the solid-state imaging device according to the first embodiment.

### 6. Sixth Embodiment

The sixth embodiment is a sixth example obtained by changing a basic stacking structure of bases in the solid-state imaging device according to the first embodiment.

### 7. Seventh Embodiment

The seventh embodiment is a seventh example obtained by changing a basic stacking structure of bases in the solid-state imaging device according to the fourth embodiment.

### 8. Eighth Embodiment

The eight embodiment is an eighth example obtained by changing a basic stacking structure of bases in the solid-state imaging device according to the fifth embodiment.

### 9. Example of Practical Application to Mobile Body

The application example will be described referring to an example where the present technology is applied to a vehicle control system as one example of a mobile body control system.

### 10. Example of Practical Application to Endoscopic Surgery System

Illustrated as the application example is an example where the present technology is applied to the endoscopic surgery system.

### 11. Other Embodiments

### 1. First Embodiment

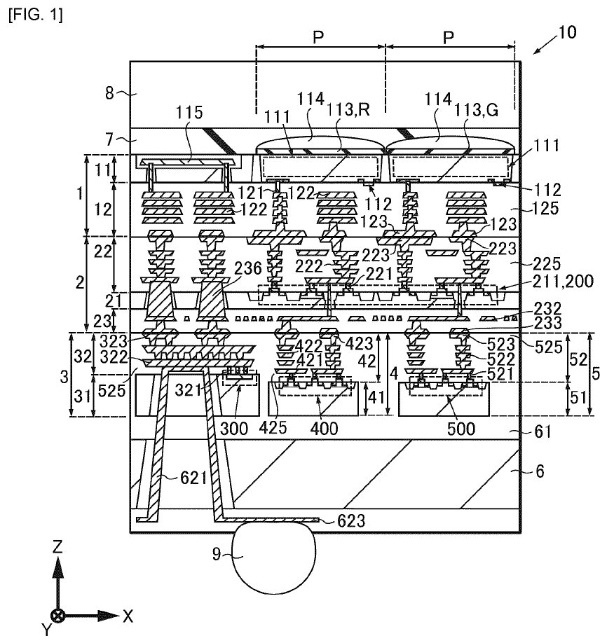

A solid-state imaging device 10 according to the first embodiment of the present disclosure will be described with reference to FIGS. 1 to 17.

Here, an arrow X direction illustrated in the drawings as appropriate illustrates one plane direction of the solid-state imaging device 10 loaded on a plane for convenience. An arrow Y direction illustrates another plane direction orthogonal to the arrow X direction. Moreover, an arrow Z direction illustrates an upward direction orthogonal to the arrow X direction and the arrow Y direction. That is, the arrow X direction, the arrow Y direction, and the arrow Z direction just respectively correspond to X-axis, Y-axis, and Z-axis directions of a three-dimensional coordinate system.

Note that each of the directions is just illustrated for helping understanding of the description and thus does not limit a direction of the present technology.

### [Configuration of Solid-State Imaging Device 10]

### (1) System Configuration of Solid-State Imaging Device 10>

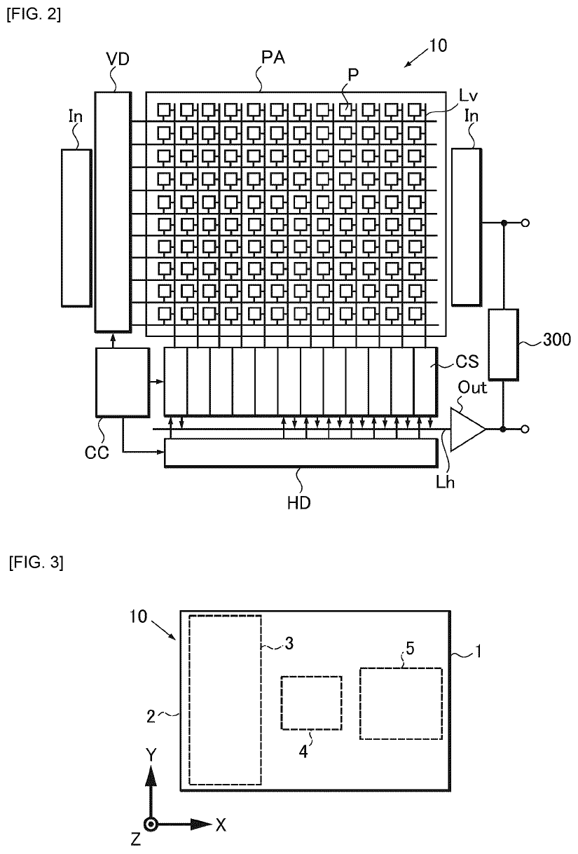

FIG. 2 illustrates one example of a system configuration of the solid-state imaging device 10 according to the first embodiment. As illustrated in FIG. 2, the solid-state imaging device 10 is built as a back-illuminated solid-state imaging device in the first embodiment. Even more specifically, the solid-state imaging device 10 is built as a complementary metal oxide semiconductor (CMOS) image sensor. Moreover, in other words, the solid-state imaging device 10 is a photodetector that converts incident light incident from an outside into electric charge. Here, incident light is incident from an arrow Z direction.

The solid-state imaging device 10 includes: a pixel area (pixel array part) PA where a plurality of pixels P is two-dimensionally and regularly arrayed; and surrounding circuits. Here, the pixels P are arrayed in an arrow X direction and an arrow Y direction.

The pixel P includes a photoelectric converter (see numeral 111 in FIG. 1) not illustrated in FIG. 2. A pixel circuit (see numeral 211 in FIG. 1) is electrically coupled to the single pixel P or each plurality of pixels P. The pixel circuit 211 is configured to include, for example, a selection transistor, an amplification transistor, and a reset transistor. The aforementioned transistors are configured by, for example, an insulated gate field effect transistor (IGFET).

Moreover, a transfer transistor that transfers, to the pixel circuit 211, electric charge obtained through conversion performed by the photoelectric conversion element 111 is electrically coupled between the pixel P and the pixel circuit 211. The transfer transistor is formed by an IGFET, as is the case with the selection transistor, etc.

Here, the pixel circuit 211 is a so-called logic circuit in the first embodiment and corresponds to “a first signal processing circuit 200” according to the present technology. Moreover, the aforementioned transfer transistor will be described as a component included in the pixel P but may also be a component included in the pixel circuit 211.

The surrounding circuits are built to include: a vertical driving circuit VD, a column signal processing circuit CS, a horizontal driving circuit HD, an output circuit Out, a control circuit CC, etc.

The control circuit CC receives an input clock and data for commanding an operation mode, etc., and outputs data such as internal information of the solid-state imaging device 10. Specifically, on the basis of a vertical synchronization signal, a horizontal synchronization signal, and a master clock, the control circuit CC generates a clock signal and a control signal that serve as reference for operation of the vertical driving circuit VD, the column signal processing circuit CS, the horizontal driving circuit HD, etc. Then the aforementioned signals are inputted to the vertical driving circuit VD, the column signal processing circuit CS, the horizontal driving circuit HD, etc.

The vertical driving circuit VD is configured by, for example, a shift register. The vertical driving circuit VD selects a pixel driving wiring and supplies the selected pixel driving wiring with a pulse for driving the pixel P. The pixel P is driven on an individual row basis. Specifically, the vertical driving circuit VD sequentially and selectively scans each pixel P of the pixel area PA on an individual row basis. Signal electric charge generated at the photoelectric conversion element 111 of each pixel P in accordance with an amount of received light is supplied as a pixel signal to the column signal processing circuit CS through the vertical signal line Lv.

The column signal processing circuit CS is disposed for, for example, each column of the pixels P. In the column signal processing circuit CS, signal processing such as noise removal is performed for each pixel column on a signal outputted from one row of the pixels P. Specifically, the column signal processing circuit CS performs signal processing such as correlated double sampling (CDS) of removing fixed pattern noise specific to the pixel P, signal amplification, analog digital (AD) conversion, etc. A horizontal selection switch, not illustrated, is coupled to a horizontal signal lines Lh at an output stage of the column signal processing circuit CS.

The horizontal driving circuit HD is configured by, for example, a shift register. The horizontal driving circuit HD sequentially outputs a horizontal scanning pulse to thereby sequentially select each column signal processing circuit CS and outputs a pixel signal from each column signal processing circuit CS to the horizontal signal line Lh.

The output circuit Out processes and outputs signals sequentially supplied through the horizontal signal line Lh from the respective column signal processing circuits CS. For example, in a case where only buffering is performed at the output circuit Out, black level adjustment, column variation correction, various digital signal processing, etc., may be performed. An input and output terminal In performs signal exchange between the solid-state imaging device 10 and an outside thereof.

Here, in the first embodiment, part of the surrounding circuits, for example, the column signal processing circuit CS, the output circuit Out, and the control circuit CC are so-called logic circuits, and corresponds to “a second signal processing circuit 400” according to the present technology. The second signal processing circuit 400 performs signal processing on the basis of an output signal from the first signal processing circuit 200.

Moreover, another part of the surrounding circuits, i.e. the vertical driving circuit VD and the horizontal driving circuit HD are so-called storage circuits and correspond to “a storage circuit 500” according to the present technology.

### [(2) Device Configuration of Solid-State Imaging Device 10]

FIG. 1 illustrates one example of a vertical cross-sectional configuration of main parts of the solid-state imaging device 10 according to the first embodiment. FIG. 3 illustrates one example of a schematic plane configuration of the solid-state imaging device 10 illustrated in FIG. 1.

As illustrated in FIG. 1, the solid-state imaging device 10 includes, as main components, a first base 1, a second base 2, and a third base 3. In the first embodiment, the solid-state imaging device 10 further includes a fourth base 4 and a fifth base 5.

Here, the bases are used, for example, in a meaning including a semiconductor element, a semiconductor chip, or a die cut from a semiconductor wafer by dicing. Moreover, in a case where a wafer-scale solid-state imaging device 10 where one pixel area PA is formed on a single semiconductor wafer is manufactured, the single semiconductor wafer is included in the base.

### [(2-1) Configuration of First Base 1]

The first semiconductor substrate 11 is processed as a die from a semiconductor wafer under manufacturing processes by dicing. The first semiconductor substrate 11 is formed into a rectangular shape when viewed in an arrow Z direction as a light incidence side (hereinafter simply referred to as “in plan view”. The shape of the first semiconductor substrate 11 is not specifically limited, but the first semiconductor substrate 11 is formed into a rectangle with the arrow X direction defined as a longitudinal direction and an arrow Y direction defined as a transverse direction. The first semiconductor substrate 11 is formed by, for example, single crystalline silicon (Si).

The photoelectric conversion element 111 is disposed at the first semiconductor substrate 11 in the region of the pixels P, the periphery of which is simply surrounded by a broken line. Here, the photoelectric conversion element 111 is formed by, for example, a photodiode. That is, the photoelectric conversion element 111 converts light incident from the arrow Z direction into electric charge.

The pixel P further includes an optical filter 113 and an optical lens 114.

The optical filter 113 is disposed at the first semiconductor substrate 11 on a side towards the arrow Z direction. The optical filter 113 includes, for example, a color filter for three colors, in total that are different for the respective pixels P. Specifically, the optical filter 113 includes: a red light filter (R) that transmits light in a red light band; a green light filter (G) that transmits light in a green light band; and a blue light filter (not illustrated) that transmits light in a blue light band. The optical filter 113 is formed by, for example, a resin material containing a dye.

The optical lens 114 is disposed at the optical filter 113 on a side opposite to the photoelectric conversion element 111. The optical lens 114 is formed into a circular shape for each pixel P, the illustration of which in plan view is omitted. Moreover, the optical lens 114 is formed into a curved shape that is curved towards a light incidence side and focuses incident light on the photoelectric conversion element 111 when viewed in the arrow Y direction (hereinafter referred to as “in a side view”).

The optical lens 114 is formed as a so-called on-chip lens and formed for each pixel P or formed integrally across the plurality of pixels P. The optical lens 114 is formed by, for example, a transparent resin material.

The aforementioned transfer transistor 112 is disposed at the first semiconductor substrate 11 on a side opposite to the arrow Z direction in a region corresponding to the pixel P. The transfer transistor 112 is configured to include: a pair of main electrodes used as a source region and a drain region; a gate insulating film; and a gate electrode, although descriptions of detailed structure and signs thereof are omitted here. The pair of main electrodes is formed by an n-type semiconductor region here. The gate insulating film is formed by, for example, silicon oxide (SiO₂). The gate electrode is formed by, for example, polycrystalline silicon (Si) with impurities introduced therein to adjust a resistance value.

The first wiring layer 12 is disposed at the first semiconductor substrate 11 on the side opposite to the arrow Z direction. The first wiring layer 12 includes plug wirings 121, wirings 122 that are multi-layered, and first terminals 123.

The wiring 122 electrically couples together the elements or the circuits. The wiring 122 is formed by a metal wiring material, for example, copper (Cu). Moreover, a metal wiring material such as, for example, an aluminum (Al)—Cu alloy may also be used for the wiring 122.

The plug wiring 121 electrically couples together the element and the wiring 122, the wirings 122, etc. A metal wiring material such as, for example, tungsten (W) or an Al—Cu alloy is used for the plug wiring 121.

The first terminal 123 is disposed at an uppermost layer of the first wiring layer 12 on the side opposite to the arrow Z direction. The first terminal 123 is electrically coupled to the wiring 122 and is electrically coupled to, for example, the second base 2 different from the first base 1. The first terminal 123 is formed by Cu here, as is the case with the wiring 122.

An insulator 125 is formed between the wirings 122 that are multi-layered, between the wiring 122 and the first terminal 123, etc., which are illustrated only in a simplified manner. The insulator 125 is formed by, for example, SiO₂.

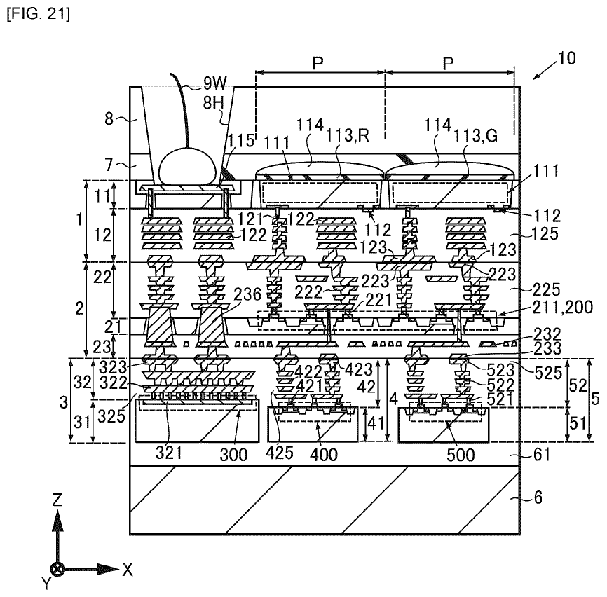

A first external terminal 115 is disposed around the pixel area PA, i.e., on the first base 1 on the side towards the arrow Z direction. The first external terminal 115 is formed by, for example, Al. The first external terminal 115 is used as an external terminal upon performing signal input or output on the light incidence side or power source input. A wire, not illustrated, is configured to be electrically or mechanically coupled to the first external terminal 115 through a wire opening, not illustrated, (see, for example, FIG. 21). For example, gold (Au) is used for the wire.

### [(2-2) Configuration of Second Base 2]

The second base 2 includes a second semiconductor substrate 21, a second wiring layer 22, and further a backside wiring layer 23.

As illustrated in FIG. 1, the second base 2 is disposed on the first base 1 on the side opposite to the arrow Z direction. That is, the second base 2 is stacked on the first base 1 in a region overlapping the first base 1.

The second semiconductor substrate 21 is processed as a die from a semiconductor wafer under manufacturing processes by dicing, as is the case with the first semiconductor substrate 11. The second semiconductor substrate 21 is formed into a rectangular shape in plan view, as is the case with the first semiconductor substrate 11. The second semiconductor substrate 21 is formed by, for example, a single crystalline Si.

The first signal processing circuit 200 including at least the pixel circuit 211 is disposed at the second semiconductor substrate 21 on a side towards the first base 1 whose detailed structure description and signs will be omitted. The first signal processing circuit 200 is configured to include active elements, for example, a transistor and passive elements, for example, a resistor, a capacitor, a coil, etc. Included as transistors are: an n-channel IGFET that has a pair of main electrodes in an n-type semiconductor region; and a p-channel IGFET that has a pair of main electrodes in a p-type semiconductor region.

The second wiring layer 22 is disposed at the second semiconductor substrate 21 on the side towards the arrow Z direction.

The second wiring layer 22 includes plug wirings 221, wirings 222 that are multi-layered, and second terminals 223.

The wiring 222 electrically couples together the elements or the circuits. The wiring 222 is formed by, for example, Cu, as is the case with the wiring 122.

The plug wiring 221 electrically couples together the element and the wiring 222, the wirings 222, etc. For example, W is used for the plug wiring 221.

The second terminal 223 is disposed at an uppermost layer of the second wiring layer 22 on the side towards the arrow Z direction. The second terminal 223 is electrically coupled to the wiring 222 and is electrically coupled to, for example, the first base 1 different from the second base 2. The second terminal 223 is formed by, for example, Cu here, as is the case with the wiring 122.

An insulator 225 is formed between the wirings 222 that are multi-layered, between the wiring 222 and the second terminal 223, etc., the illustration of which is provided in a simple manner. The insulator 225 is formed by, for example, SiO₂.

The second terminal 223 of the second base 2 is electrically and mechanically bonded to the first terminal 123 of the first base 1 in a face-to-face manner. Here, Cu is used for each of the first terminal 123 and the second terminal 223, and thus the bonding of the first terminal 123 and the second terminal 223 is Cu—Cu bonding.

The backside wiring layer 23 is disposed at the second semiconductor substrate 21 on the side opposite to the arrow Z direction. The backside wiring layer 23 includes through-wirings 231, wirings 232 that are multi-layered, and a back terminal 233.

The wiring 232 electrically couples together the elements or the circuits. The wiring 232 is formed by, for example, Cu, as is the case with the wiring 122.

The through-wiring 231 penetrates the second semiconductor substrate 21 in a thickness direction and electrically couples together the wiring 222 of the second wiring layer 22 and the wiring 232 of the backside wiring layer 23. For the through-wiring 231, for example, one or more selected from W, cobalt (Co), ruthenium (Ru), Cu, Al, and molybdenum (Mo) is used. Moreover, the through-wiring 231 has a cross-sectional diameter, for example, equal to or more than 0.02 μm and equal to or less than 0.5 μm.

The back terminal 233 is disposed at an uppermost layer of the backside wiring layer 23 on the side opposite to the arrow Z direction. The back terminal 233 is electrically coupled to the wiring 232 and electrically couples together a third base 3, a fourth base 4, a fifth base 5, etc., that are different from the second base 2. The back terminal 233 is formed by Cu here, as is the case with the wiring 232.

An insulator 235 is formed between the wirings 232 that are multi-layered, between the wiring 232 and the back terminal 233, etc., an illustration of which is simplified. The insulator 235 is formed by, for example, SiO₂.

### [(2-3) Configuration of Fourth Base 4]

The fourth base 4 includes a fourth semiconductor substrate 41 and a fourth wiring layer 42.

As illustrated in FIG. 1, the fourth base 4 is disposed on the second base 2 on the side opposite to the arrow Z direction. Specifically, the fourth base 4 is stacked on the second base 2 in a region overlapping the first base 1 and the second base 2.

The fourth semiconductor substrate 41 is processed as a die from a semiconductor wafer under manufacturing processes by dicing, as is the case with the first semiconductor substrate 11. The fourth semiconductor substrate 41 is formed into a rectangular shape in plan view, as is the case with the first semiconductor substrate 11. As illustrated in FIG. 3, the fourth semiconductor substrate 41 is formed into a square shape that is smaller than a plane area of each of the first semiconductor substrate 11 and the second semiconductor substrate 21. The fourth semiconductor substrate 41 is disposed in a middle part of each of the first semiconductor substrate 11 and the second semiconductor substrate 21 in an arrow X direction. In other words, the fourth base 4 including the fourth semiconductor substrate 41 is stacked in the middle part of the first base 1 and the second base 2 in the arrow X direction. The fourth semiconductor substrate 41 is formed by, for example, a single crystalline Si.

The second signal processing circuit 400 including at least part of the surrounding circuits is disposed at the fourth semiconductor substrate 41 on the side towards the first base 1. The second signal processing circuit 400 is configured to include active elements, for example, a transistor and passive elements, for example, a resistor, a capacitor, a coil, etc., whose detailed structure illustration and sings are omitted. An n-channel IGFET and a p-channel IGFET are included as transistors.

The fourth wiring layer 42 is disposed at the fourth semiconductor substrate 41 on the side towards the arrow Z direction. The fourth wiring layer 42 includes a plug wiring 421, wirings 422 that are multi-layered, and a fourth terminal 423.

The wiring 422 electrically couples together the elements or the circuits. The wiring 422 is formed by, for example, Cu, as is the case with the wiring 122.

The plug wiring 421 electrically couples together the element and the wirings 422, the wirings 422, etc. For example, W is used for the plug wiring 421.

The fourth terminal 423 is disposed at an uppermost layer of the fourth wiring layer 42 on the side towards the arrow Z direction. The fourth terminal 423 is electrically coupled to the wiring 422 and electrically coupled to, for example, the second base 2 different from the fourth base 4. The fourth terminal 423 is formed by Cu here, as is the case with the wiring 122.

An insulator 425 is formed between the wirings 422 that are multi-layered, between the wiring 422 and the fourth terminal 423, etc., an illustration of which is simplified. The insulator 425 is formed by, for example, SiO₂.

The fourth terminal 423 of the fourth base 4 is electrically and mechanically bonded to the back terminal 233 of the second base 2 in a face-to-face manner. Here, Cu is used for each of the back terminal 233 and the fourth terminal 423, and thus the bonding of the back terminal 233 and the fourth terminal 423 is Cu—Cu bonding.

### [(2-4) Configuration of Fifth Base 5]

The fifth base 5 includes a fifth semiconductor substrate 51 and a fifth wiring layer 52.

As illustrated in FIG. 1, the fifth base 5 is disposed on the second base 2 on the side opposite to the arrow Z direction. Specifically, the fifth base 5 is stacked on the second base 2 in a region overlapping the first base 1 and the second base 2.

The fifth semiconductor substrate 51 is processed as a die from a semiconductor wafer under manufacturing processes by dicing, as is the case with the first semiconductor substrate 11. The fifth semiconductor substrate 51 is formed into a rectangular shape in plan view, as is the case with the first semiconductor substrate 11. As illustrated in FIG. 3, the fifth semiconductor substrate 51 is formed into a square shape that is smaller than a plane area of each of the first semiconductor substrate 11 and the second semiconductor substrate 21 and larger than a plane area of the fourth semiconductor substrate 41. The fifth semiconductor substrate 51 is disposed on a side of each of the first semiconductor substrate 11 and the second semiconductor substrate 21 towards the arrow X direction. In other words, the fifth base 5 including the fifth semiconductor substrate 51 described above is stacked adjacently to the fourth base 4 on the side of the first base 1 and the second base 2 towards the arrow X direction. The fifth semiconductor substrate 51 is formed by, for example, a single crystalline Si.

A storage circuit 500 including at least another part of the surrounding circuits is disposed at the fifth semiconductor substrate 51 on the side towards the first base 1. The storage circuit 500 is configured to include active elements, for example, a transistor and passive elements, for example, a resistor, a capacitor, etc., a detailed structure description and signs of which are omitted.

The fifth wiring layer 52 is disposed at the fifth semiconductor substrate 51 on the side towards the arrow Z direction. The fifth wiring layer 52 includes a plug wiring 521, wirings 522 that are multi-layered, and a fifth terminal 523.

The wiring 522 electrically couples together the elements or the circuits. The wiring 522 is formed by, for example, Cu, as is the case with the wiring 122.

The plug wiring 521 electrically couples together the element and the wiring 522, the wirings 522, etc. For example, W is used for the plug wiring 521.

The fifth terminal 523 is disposed at an uppermost layer of the fifth wiring layer 52 on the side towards the arrow Z direction. The fifth terminal 523 is electrically coupled to the wirings 522 and electrically coupled to, for example, the second base 2 different from the fifth base 5. The fifth terminal 523 is formed by, for example, Cu, as is the case with the wiring 122.

An insulator 525 is formed between the wirings 522 that are multi-layered, between the wirings 522 and the fifth terminal 523, etc., an illustration of which is simplified. The insulator 525 is formed by, for example, SiO₂.

The fifth terminal 523 of the fifth base 5 is electrically and mechanically bonded to the back terminal 233 of the second base 2 in a face-to-face manner. Here, Cu is used for each of the back terminal 233 and the fifth terminal 523, and thus the bonding of the back terminal 233 and the fifth terminal 523 is Cu—Cu bonding.

### [(2-5) Configuration of Third Base 3 (Configuration of Protection Element 300)]

The third base 3 includes a third semiconductor substrate 31 and a third wiring layer 32.

As illustrated in FIG. 1, the third base 3 is disposed on the second base 2 on the side opposite to the arrow Z direction. Specifically, the third base 3 is stacked on the second base 2 in a region overlapping the first base 1 and the second base 2.

The third semiconductor substrate 31 is processed as a die from a semiconductor wafer under manufacturing processes by dicing, as is the case with the first semiconductor substrate 11. The third semiconductor substrate 31 is formed into a rectangular shape in plan view, as is the case with the first semiconductor substrate 11.

As illustrated in FIG. 3, the third semiconductor substrate 31 is formed into a rectangular shape having a plane area that is smaller than the plane area of each of the first semiconductor substrate 11 and the second semiconductor substrate 21 and larger than plane areas of the fourth semiconductor substrate 41 and the fifth semiconductor substrate 51. The third semiconductor substrate 31 is formed with a shorter direction extending in the arrow X direction and a longitudinal direction extending in the arrow Y direction here.

The third semiconductor substrate 31 is disposed on a side opposite to the arrow X direction of each of the first semiconductor substrate 11 and the second semiconductor substrate 21. In other words, the third base 3 including the third semiconductor substrate 31 is stacked adjacently to the fourth base 4 on the side opposite to the arrow X direction of the first base 1 and the second base 2. The third semiconductor substrate 31 is formed by, for example, a single crystalline Si.

The protection element 300 is disposed at the third semiconductor substrate 31 on the side towards the first base 1. The protection element 300 is electrically coupled to each of the first signal processing circuit 200, the second signal processing circuit 400, and the storage circuit 500 and absorbs an overcurrent as a dedicated protection element shared by the aforementioned circuits.

More specifically describing, the protection element 300 absorbs an overcurrent on products during or after the manufacturing processes after assembled as the solid-state imaging device 10. Therefore, the protection element 300 is disposed, for example, between the first external terminal 115 or a second external terminal 623 (see FIG. 1) to be described later on and the first signal processing circuit 200 as a protection target. Further, the protection element 300 is inserted at a signal input stage and a signal output stage and on a power supply path.

In the first embodiment, the protection element 300 is formed to include a protection diode. The protection diode is formed to, for example, have, as an anode region, a p-type third semiconductor substrate 31 and have, as a cathode region, an n-type semiconductor region disposed at a surface portion of the third semiconductor substrate 31.

Note that the protection element 300 may be built by active elements, for example, a transistor and passive elements, for example, a resistor, a capacitor, a coil, etc., instead of the protection diode. Further, the protection element 300 may be built by adding a passive element to the protection diode.

The third wiring layer 32 is disposed at the third semiconductor substrate 31 on the side towards the arrow Z direction. The third wiring layer 32 includes a plug wiring 321, wirings 322 that are multi-layered, and a third terminal 323.

For example, the wirings 322 electrically couples together, for example, the first signal processing circuit 200 and the protection element 300. The wiring 322 is formed by, for example, Cu, as is the case with the wiring 122.

The plug wiring 321 electrically couples together the protection element 300 and the wirings 322, the wirings 322, etc. For example, W is used for the plug wiring 321.

The third terminal 323 is disposed at an uppermost layer of the third wiring layer 32 on the side towards the arrow Z direction. The third terminal 323 is electrically coupled to the wirings 322 and electrically coupled to, for example, the second base 2 different from the third base 3. The third terminal 323 is formed by, for example, Cu, as is the case with the wiring 122.

An insulator 325 is formed between the wirings 322 that are multi-layered, between the wirings 322 and the third terminal 323, etc., an illustration of which is simplified. The insulator 325 is formed by, for example, SiO₂.

The third terminal 323 of the third base 3 is electrically and mechanically bonded to the back terminal 233 of the second base 2 in a face-to-face manner. Here, Cu is used for each of the back terminal 233 and the third terminal 323, and thus the bonding of the back terminal 233 and the third terminal 323 is Cu—Cu bonding.

Here, the back terminal 233 bonded to the third terminal 323 is coupled to the second wiring layer 22 of the second base 2 through the wiring 232 and a through-wiring 236 of the backside wiring layer 23. The through-wiring 236 penetrates the second semiconductor substrate 21 of the second base 2 in the thickness direction. The through-wiring 236 has a larger cross-sectional area than, for example, the through-wiring 231. More specifically, the through-wiring 236 has a cross-sectional diameter, for example, equal to or more than 0.5 μm and equal to or less than 5 μm. Further, the through-wiring 236 is formed by, for example, a conductive material containing Cu or Al. Thus, the through-wiring 236 has a smaller resistance value than the through-wiring 231. The through-wiring 236 corresponds to “a first through-wiring” according to the present technology.

### [(2-6) Configuration of Support Base 6]

As illustrated in FIG. 1, the first base 1 to the fifth base 5 are stacked on the support base 6 in the arrow Z direction. The first base 1 and the second base 2 are stacked, and the third base 3 to the fifth base 5 are effectively stacked as a first layer on the second base 2. Therefore, in the first embodiment, the solid-state imaging device 10 is built by a three-layer structure in which, excluding the support base 6, the third base 3 to the fifth base 5 are disposed at a lowermost layer on a side towards the support base 6, the second base 2 is disposed at a middle layer, and the first base 1 is disposed at an uppermost layer.

It is possible to use, for example, any of an Si substrate, a glass substrate, etc., for the support base 6.

The second external terminal 623 is disposed at the support base 6 on the side opposite to the arrow Z direction. The second external terminal 623 is electrically coupled to the third wiring layer 32 of the third base 3 through a through-wiring 621 that penetrates each of the support base 6 and the third semiconductor substrate 31 of the third base 3 in the thickness direction. That is, the second external terminal 623 is electrically coupled to the protection element 300. The second external terminal 623 is formed by, for example, Cu. The through-wiring 621 corresponds to “a second through-wiring” according to the present technology.

A bump electrode 9 is electrically and mechanically coupled to the second external terminal 623 with a barrier metal, not illustrated, in between. The bump electrode 9 is formed by a solder material such as a tin (Sn)-silver (Ag)—Cu alloy, a Sn—Cu alloy, or a Sn-bismuth (Bi) alloy. Moreover, it is possible to use, for the bump electrode 9, Cu or a composite material in which Cu is stacked on nickel (Ni).

It is possible to use, for a barrier metal, for example, titanium (Ti), titanium nitride (TIN), Ni, cobalt (Co), tantalum (Ta), or tantalum nitride (TaN).

Note that the support base 6 may be removed as a final product of the solid-state imaging device 10.

### [(2-7) Configuration of Transparent Substrate 8]

As illustrated in FIG. 1, the transparent substrate 8 is disposed at the optical lens 114 of the first base 1 with a protection film 7 in between.

The protection film 7 is formed by, for example, glass seal resin. The transparent substrate 8 is formed by, for example, a glass substrate.

### [Method for Manufacturing Solid-state Imaging Device 10]

The method for manufacturing the solid-state imaging device 10 according to the first embodiment is as follows.

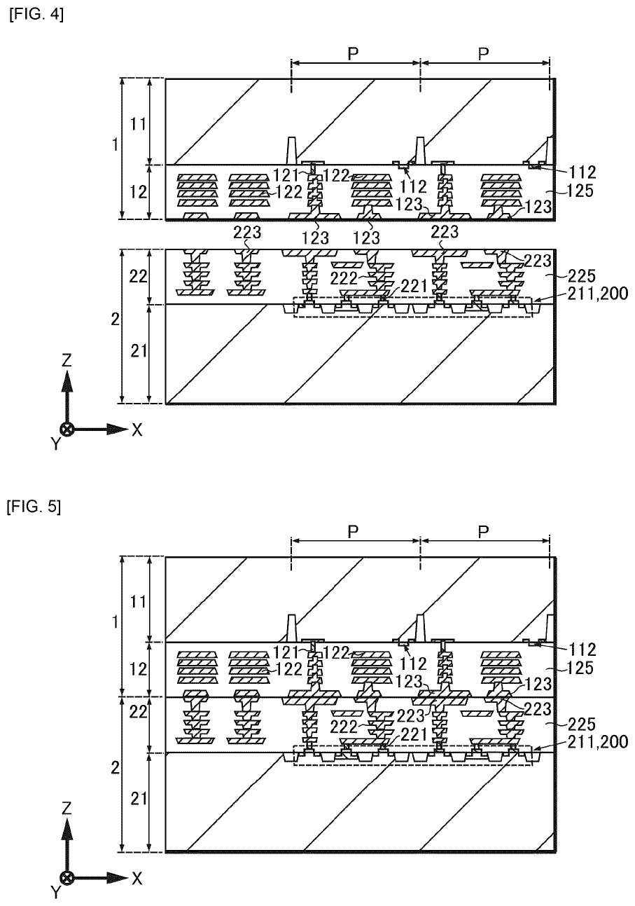

First, as illustrated in FIG. 4, each of the first base 1 and the second base 2 is prepared.

The first base 1 includes the first semiconductor substrate 11 processed as a die from a semiconductor wafer by dicing. The first wiring layer 12 is formed at the first semiconductor substrate 11 and the first terminals 123 of the first wiring layer 12 are in an exposed state.

On the other hand, the second base 2 includes the second semiconductor substrate 21 processed as a die from a single semiconductor wafer, which is different from the semiconductor wafer of the first base 1, by dicing. The second wiring layer 22 is formed at the second semiconductor substrate 21 and the second terminals 223 of the second wiring layer 22 are in an exposed state.

As illustrated in FIG. 5, the first terminals 123 of the first base 1 and the second terminals 223 of the second base 2 are placed to face each other and the first terminal 123 and the second terminal 223 are bonded together. The bonding adopted here is Cu—Cu bonding. As a result, the second base 2 is stacked on the first base 1.

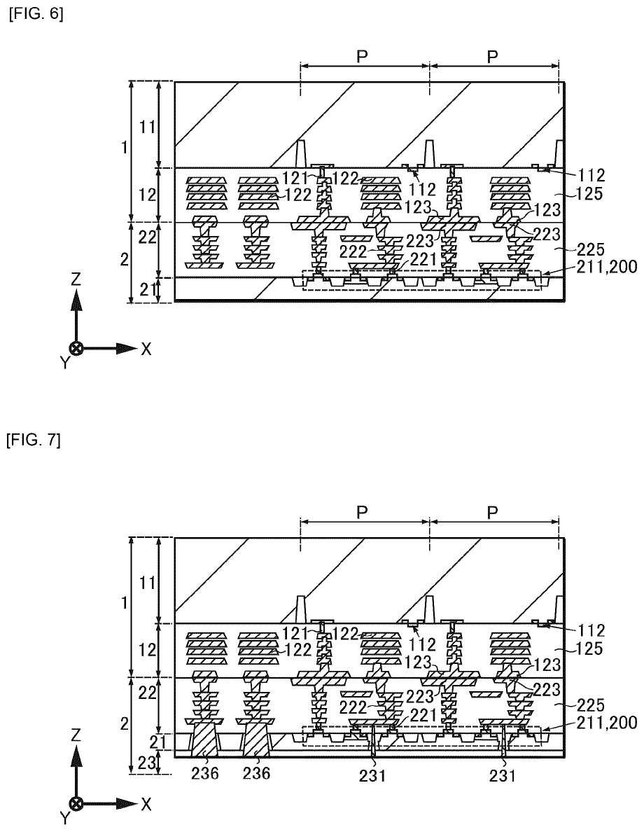

As illustrated in FIG. 6, the second semiconductor substrate 21 of the second base 2 on a side opposite to the first base 1 is thinned. For the thinning, for example, back grind (BGR) treatment or chemical mechanical polishing (CMP) treatment is used.

As illustrated in FIG. 7, each of the through-wirings 231 and the through-wirings 236 that extend from the second wiring layer 22 and penetrate the second semiconductor substrate 21 in the thickness direction is formed on the second base 2.

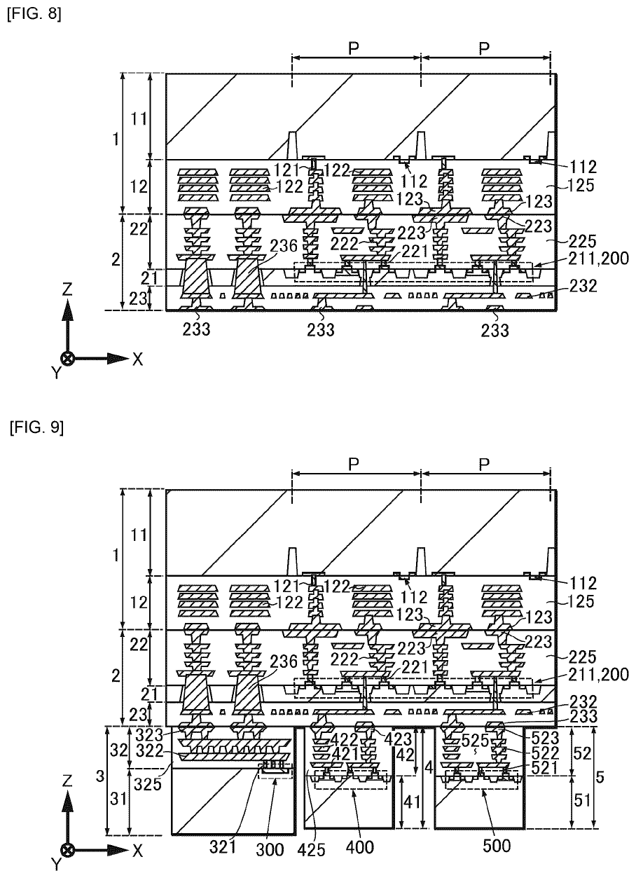

As illustrated in FIG. 8, each of the wirings 232 and the back terminals 233 is sequentially formed, and the backside wiring layer 23 of the second base 2 is formed.

Next, each of the third base 3 having the protection element 300, the fourth base 4 having the second signal processing circuit 400, and the fifth base 5 having the storage circuit 500 is prepared (see FIG. 9).

The fourth base 4 includes the fourth semiconductor substrate 41 processed as a die from a semiconductor wafer, which is different from the semiconductor wafers of the first base 1 and the second base 2, by dicing. The fourth wiring layer 42 is formed at the fourth semiconductor substrate 41 and the fourth terminal 423 of the fourth wiring layer 42 is in an exposed state.

The fifth base 5 includes the fifth semiconductor substrate 51 processed as a die from a semiconductor wafer, which is different from the semiconductor wafers of the first base 1, the second base 2, and the fourth base 4, by dicing. The fifth wiring layer 52 is formed at the fifth semiconductor substrate 51 and the fifth terminal 523 of the fifth wiring layer 52 is in an exposed state.

Then the third base 3 includes the third semiconductor substrate 31 processed as a die, a semiconductor wafer, which is different from the semiconductor wafers of the first base 1, the second base 2, the fourth base 4, and the fifth base 5, by dicing. The third wiring layer 32 is formed at the third semiconductor substrate 31 and the third terminal 323 of the third wiring layer 32 is in an exposed state.

As illustrated in FIG. 9, the back terminal 233 of the second base 2 and the fourth terminal 423 of the fourth base 4 are placed to face each other and the back terminal 233 and the fourth terminal 423 are bonded together. Similarly, the back terminal 233 of the second base 2 and the fifth terminal 523 of the fifth base 5 are placed to face each other and the back terminal 233 and the fifth terminal 523 are bonded together. Further, the back terminal 233 of the second base 2 and the third terminal 323 of the third base 3 are bonded together in a face-to-face manner. The bonding adopted here is Cu—Cu bonding. As a result, the third base 3, the fourth base 4, and the fifth base 5 are stacked on the second base 2.

Then since the third base 3 having the protection element 300 has been assembled, an overcurrent generated during the manufacturing processes thereafter or after completion of the product is absorbed by the protection element 300

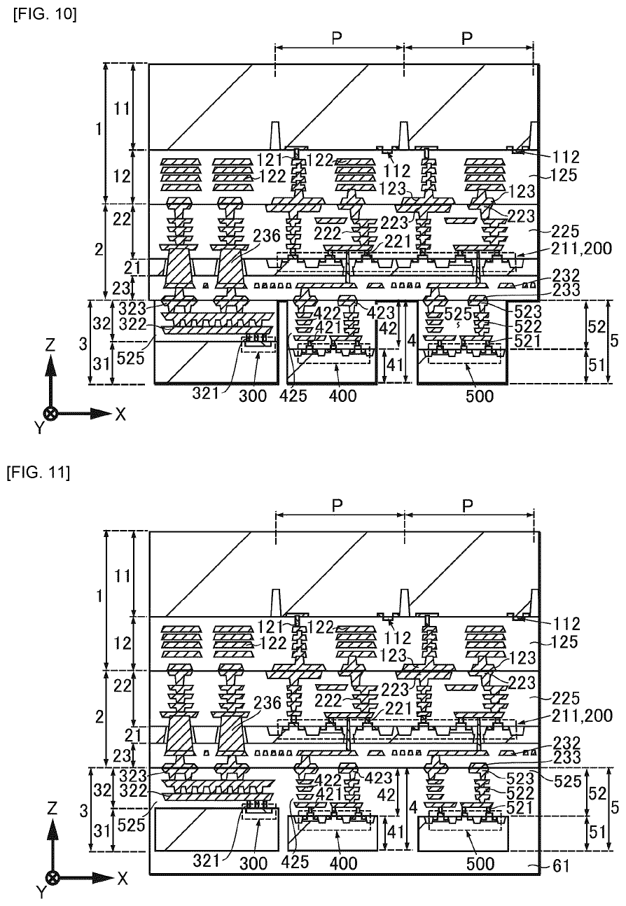

As illustrated in FIG. 10, each of the third semiconductor substrate 31 of the third base 3, the fourth semiconductor substrate 41 of the fourth base 4, and the fifth semiconductor substrate 51 of the fifth base 5 is thinned. BGR treatment or CMP treatment is used for the thinning, as described above.

As illustrated in FIG. 11, each of the third base 3, the fourth base 4, and the fifth base 5 is embedded by an embedding member 61.

For example, an inorganic material such as SiO₂ or silicon nitride (SiN) is used for the embedding member 61. The inorganic material is formed using, for example, a chemical vapor deposition (CVD) method, a vapor deposition method, a sputtering method, or a coating method.

Moreover, it is possible to use, for the embedding member 61, one or more organic materials selected from epoxy resin, polymer, polyimide resin, and poly ether ether ketone resin. The organic material is formed using a dip method or a spray method.

The embedding member 61 has a heat resistance temperature equal to or more than 100° C. and equal to or less than 500° C.

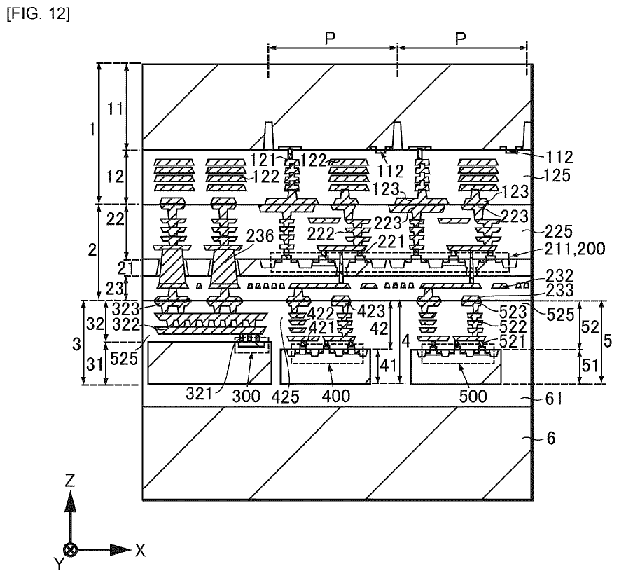

As illustrated in FIG. 12, the support base 6 is bonded to the embedding member 61. Bonding using an adhesive or bonding using an oxide film is used for the bonding. For example, an Si substrate or a glass substrate with a thickness of equal to or more than 300 μm and equal to or less than 800 μm is used for the support base 6.

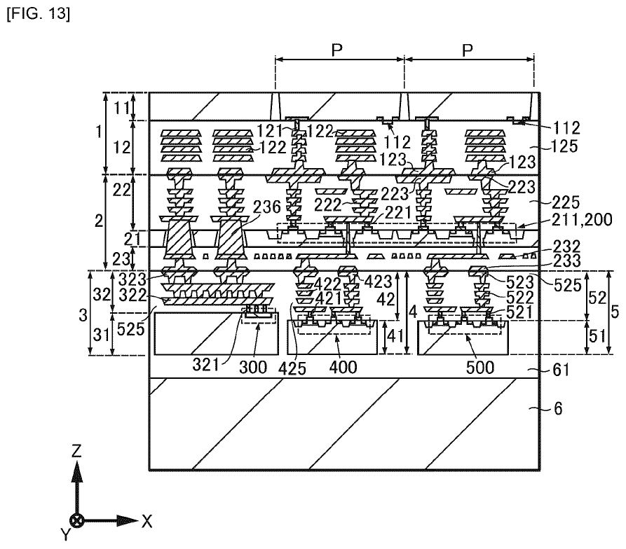

Next, as illustrated in FIG. 13, the first semiconductor substrate 11 of the first base 1 is thinned. The first semiconductor substrate 11 is formed with a thickness of, for example, equal to or more than 2 μm and equal to or less than 20 μm. For example, CMP treatment or etching treatment is used for the thinning.

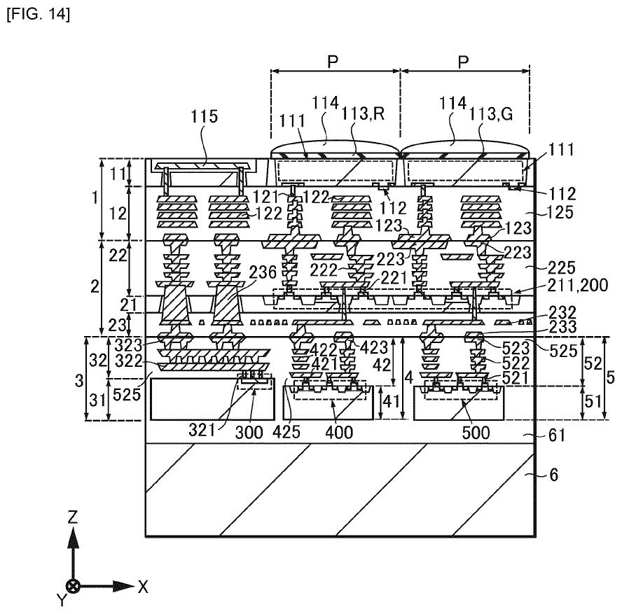

As illustrated in FIG. 14, the pixels P are formed at the first semiconductor substrate 11 of the first base 1. For the formation of the pixels P, the photoelectric conversion element 111 is formed at the first semiconductor substrate 11. Thereafter, the optical filter 113 and the optical lens 114 are each sequentially formed.

Moreover, the first external terminal 115 is formed at the first semiconductor substrate 11 in a surrounding area of the first base 1.

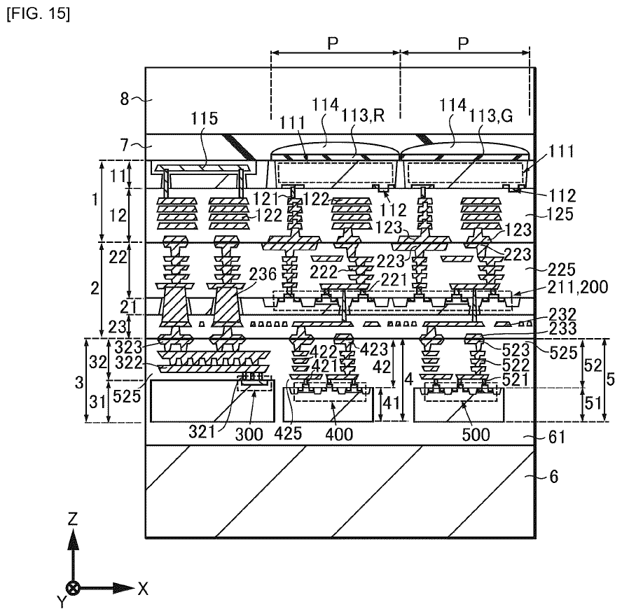

As illustrated in FIG. 15, the protection film 7 that covers the optical lens 114 is formed and the transparent substrate 8 that covers the protection film 7 is subsequently formed.

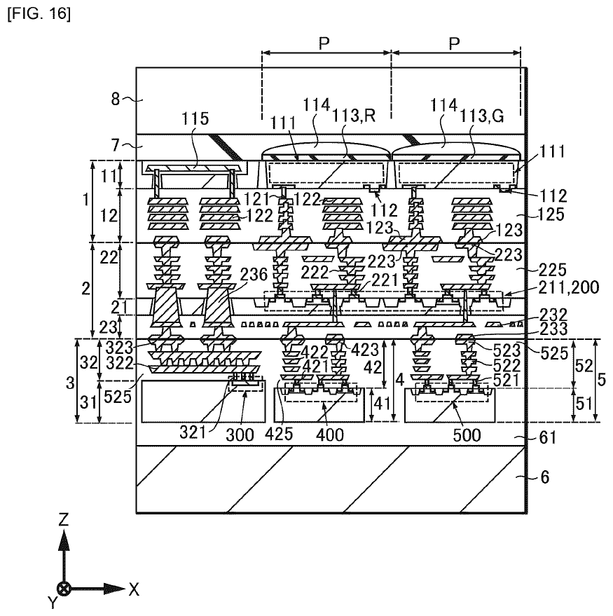

As illustrated in FIG. 16, the support base 6 is thinned. BGR treatment or CMP treatment is used for the thinning. The support base 6 is formed with a thickness, for example, equal to or more than 50 μm and equal to or less than 100 μm. Note that when the support base 6 is not required as a final product, the support base 6 is removed at this stage.

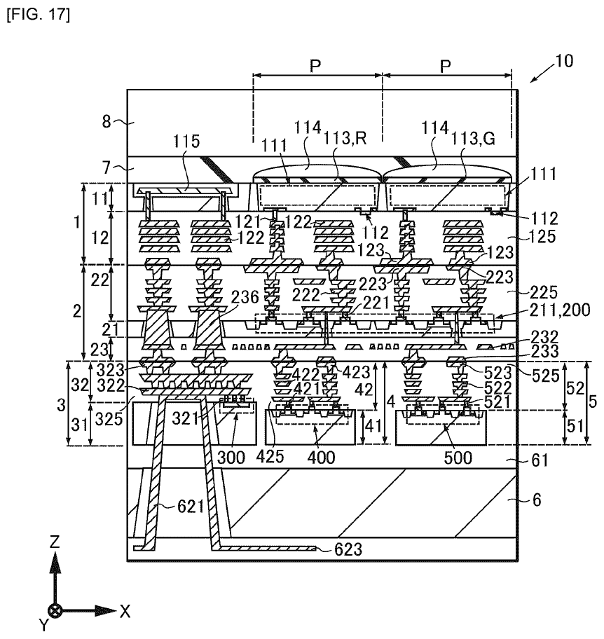

As illustrated in FIG. 17, the through-wiring 621 that penetrates the support base 6 and the third semiconductor substrate 31 of the third base 3 is formed, and the second external terminal 623 to be electrically coupled to the through-wiring 621 is formed.

Upon the formation of the through-wiring 621, the second external terminal 623 is electrically coupled to the protection element 300 through each of the through-wiring 621 and the third wiring layer 32. Moreover, although not used in the first embodiment, at a stage where the third base 3 is stacked on the second base 2 in the process illustrated in FIG. 9, the first external terminal 115 is electrically coupled to the protection element 300 through each of the first wiring layer 12, the second wiring layer 22, the through-wiring 236, the backside wiring layer 23, and the third wiring layer 32. Further, the protection element 300 is also electrically coupled to the first signal processing circuit 200, the second signal processing circuit 400, the storage circuit 500, etc.

This therefore allows the protection element 300 to absorb an overcurrent generated through a dry process (for example, dry etching) used, for example, upon forming the through-wiring 621 under the manufacturing processes.

As illustrated in FIG. 1 described above, the bump electrode 9 is formed at the second external terminal 623.

At time of ending of a series of manufacturing processes, the solid-state imaging device 10 according to the first embodiment is completed.

### [Workings and Effects]

As described above, the solid-state imaging device 10 according to the first embodiment includes the first base 1, the second base 2, and the third base 3 as illustrated in FIGS. 1 to 3.

The first base 1 has the photoelectric conversion element 111 that convers light into electric charge. The second base 2 has the first signal processing circuit 200 that performs signal processing on the basis of the electric charge obtained by the conversion performed by the photoelectric conversion element 111. The second base 2 is different from the first base 1. The third base 3 has the protection element 300 that is electrically coupled to the first signal processing circuit 200 and absorbs an overcurrent. The third base 3 is different from the first base 1 and the second base 2.

In other words, the third base 3 is provided which has the dedicated protection element 300 shared by each of the first base 1 and the second base 2.

Thus, the semiconductor wafers respectively forming the first base 1 and the second base 2 do not specifically require any protection element. That is, it is possible to increase the number of first bases 1 that are obtainable from the semiconductor wafer or the number of second bases 2 that are obtainable from the semiconductor wafer.

Moreover, it is possible to increase the number of first bases 1 and the number of the second bases 2 that are obtainable from the semiconductor wafers, this allows reduction in manufacture costs and product costs of the solid-state imaging device 10.

Moreover, as illustrated in FIGS. 1 and 3, each of the second base 2 and the third base 3 is stacked on the first base 1 in the solid-state imaging device 10. More specifically, the third base 3 is stacked on the first base 1 with the second base 2 in between.

The first base 1 includes the first wiring layer 12 having the first terminals 123 on a side opposite to a light incidence side. The second base 2 includes the second wiring layer 22 having the second terminals 223 on the side towards the first base 1. The first terminal 123 and the second terminal 223 are bonded together in a face-to-face manner. Then each of the first terminal 123 and the second terminal 223 is formed by Cu, and the bonding of the first terminal 123 and the second terminal 223 is Cu—Cu bonding.

Thus, it is possible to build a three-dimensional structure with the first base 1 to the third base 3 stacked in the arrow Z direction, thus allowing downsizing of the solid-state imaging device 10 in the arrow X direction and the arrow Y direction.

Moreover, as illustrated in FIG. 1, the solid-state imaging device 10 further includes the first external terminal 115 disposed on the first base 1 on the light incidence side. The protection element 300 is electrically coupled to the first external terminal 115 through the through-wiring (first through-wiring) 236 that penetrates the second base 2 in the thickness direction. A wire, not illustrated, is electrically coupled to the first external terminal 115.

This therefore allows the protection element 300 to absorb an overcurrent at time of inputting the overcurrent to the first external terminal 115. Therefore, it is possible to provide the solid-state imaging device 10 with excellent protection performance against an overcurrent.

Moreover, as illustrated in FIG. 1, the solid-state imaging device 10 further includes the second external terminal 623 disposed on the third base 3 on the side opposite to the first base 1. The protection element 300 is electrically coupled to the second external terminal 623 through the through-wiring (second through-wiring) 621 that penetrates the third base 3 in the thickness direction. The bump electrode 9 is electrically coupled to the second external terminal 623.

This therefore allows the protection element 300 to absorb an overcurrent at time of inputting the overcurrent to the second external terminal 623. Therefore, it is possible to provide a solid-state imaging device 10 with excellent protection performance against an overcurrent.

Moreover, as illustrated in FIG. 1, the protection element 300 in the solid-state imaging device 10 includes a diode.

This therefore allows the protection element 300 to efficiently absorb an overcurrent to the third semiconductor substrate 31, thus making it possible to provide a solid-state imaging device 10 with excellent protection performance against an overcurrent.

In addition, the protection element 300 in the solid-state imaging device 10 includes one or more selected from a capacitor, a resistor, and a coil.

This therefore allows the protection element 300 to even more efficiently absorb an overcurrent with, for example, the capacitor in addition to the diode, thus making it possible to provide a solid-state imaging device 10 with excellent protection performance against an overcurrent.

Moreover, the solid-state imaging device 10 includes each of the fourth base 4 and the fifth base 5, as illustrated in FIG. 1.

The fourth base 4 has the second signal processing circuit 400 that performs signal processing on the basis of the electric charge obtained by the conversion performed by the photoelectric conversion element 111 or performs signal processing on the basis of an output signal from the first signal processing circuit 200. The fourth base 4 is different from the first base 1, the second base 2, and the third base 3.

The fifth base 5 has the storage circuit 500 that stores the output signal from the first signal processing circuit 200. The fifth base 5 is different from the first base 1, the second base 2, the third base 3, and the fourth base 4.

Thus, it is possible to increase the number of fourth bases 4 that are obtainable from the semiconductor wafer or the number of fifth bases 5 that are obtainable from the semiconductor wafer.

### 2. Second Embodiment

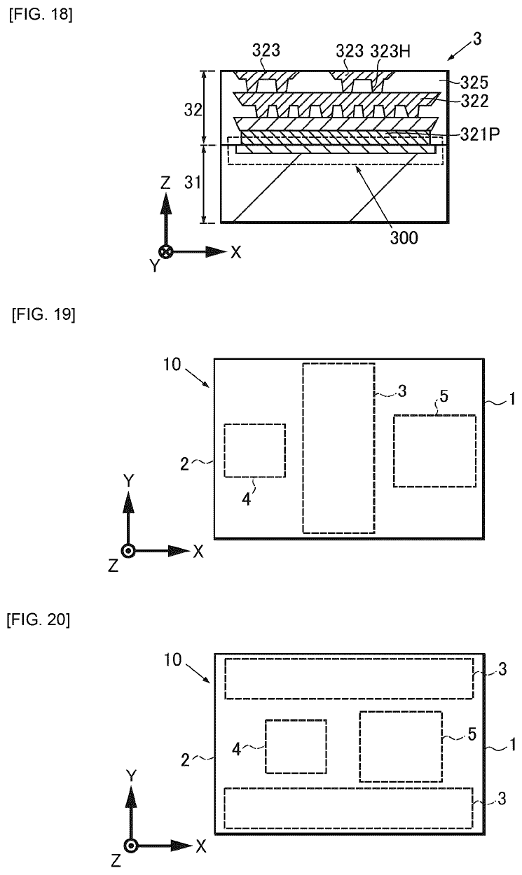

A solid-state imaging device 10 according to the second embodiment of the present disclosure will be described with reference to FIG. 18,

Note that the same or substantially the same components in the second embodiment and the embodiments thereafter as the components of the solid-state imaging device 10 according to the first embodiment will be provided with the same signs, and an overlapping description will be omitted.

### [Configuration of Third Base 3 of Solid-state Imaging Device 10]

FIG. 18 illustrates one example of an enlarged vertical cross-sectional configuration of main parts of the solid-state imaging device 10 according to the second embodiment. The solid-state imaging device 10 according to the second embodiment is obtained by changing the configuration of the third base 3 of the solid-state imaging device 10 according to the first embodiment, which will be described in detail below.

As illustrated in FIG. 18, in the solid-state imaging device 10 according to the second embodiment, an electrode 321P that is electrically coupled to a protection element 300 of the third base 3 is formed into a plate-like shape (a plate structure). Here, the protection element 300 is formed by a diode, as is the case with the protection element 300 in the first embodiment. That is, the electrode 321P is electrically coupled to a cathode region of the diode.

The electrode 321P is disposed at a lowermost layer of a third wiring layer 32. In plan view, the electrode 321P has a larger plane area than a plane area of a coupling hole 323H that electrically couples together third terminals 323 and wiring 322. Here, the electrode 321P is formed into a plate-like shape corresponding to a shape obtained by continuously disposing a plurality of coupling holes 323H in an arrow X direction and an arrow Y direction. In other words, the electrode 321P is disposed flush against the protection element 300. The electrode 321P is formed by, for example, a metal material that is similar to a metal material of a plug wiring 321.

The components other than the components described above are the same or substantially the same as the components of the solid-state imaging device 10 according to the first embodiment described above, and a description of the overlapping components will be omitted.

### [Workings and Effects]

With the solid-state imaging device 10 according to the second embodiment, it is possible to provide workings and effects similar to the workings and effects provided by the solid-state imaging device 10 according to the first embodiment.

Moreover, as illustrated in FIG. 18, the third wiring layer 32 of the third base 3 in the solid-state imaging device 10 includes at least the electrode 321P, the wiring 322, and the third terminals 323. The electrode 321P is disposed at the protection element 300. The wiring 322 is disposed at the electrode 321P on a side opposite to the protection element 300. The third terminals 323 are disposed at the wiring 322 on a side not facing the protection element 300.

Then when viewed in the thickness direction of the third base 3, the plane area of the electrode 321P is smaller than a plane area of the protection element 300 and larger than the plane area of the coupling hole 323H between the third terminal 323 and the wiring 322. Here, the electrode 321P is formed into a plate-like shape.

Thus, it is possible to increase a cross-sectional area of the electrode 321P as a current path, thus making it possible to effectively suppress or prevent current concentration on the current path and efficiently input an overcurrent to the protection element 300. Thus, it is possible to provide a solid-state imaging device 10 with excellent protection performance against an overcurrent.

The solid-state imaging device 10 according to the second embodiment is applicable to all the solid-state imaging devices 10 according to the embodiments described thereafter.

### 3. Third Embodiment

The solid-state imaging device 10 according to the third embodiment of the present disclosure will be described with reference to FIGS. 19 and 20.

### [Configuration of Solid-state Imaging Device 10]

FIG. 19 illustrates one example of a schematic plane configuration of the solid-state imaging device 10 according to the third embodiment. The solid-state imaging device 10 according to the third embodiment is obtained by changing the disposition positions of the third base 3 to the fifth base 5 with respect to the first base 1 and the second base 2 in the solid-state imaging device 10 according to the first embodiment, which will be described in detail below.

As illustrated in FIG. 19, in the solid-state imaging device 10 according to the third embodiment, the third base 3 having a protection element 300 is disposed at a middle part of the first base 1 and the second base 2 in an arrow X direction. The fourth base 4 is disposed adjacently to the third base 3 on a side opposite to the arrow X direction. Then the fifth base 5 is disposed adjacently to the third base 3 on a side towards the arrow X direction.

The components other than the components described above are the same or substantially the same as the components of the solid-state imaging device 10 according to the first embodiment described above, and thus an overlapping description of the components will be omitted.

### [Workings and Effects]

With the solid-state imaging device 10 according to the third embodiment, it is possible to provide the workings and effects similar to the workings and effects provided by the solid-state imaging device 10 according to the first embodiment.

Moreover, as illustrated in FIG. 19, the third base 3 is disposed at the middle part with respect to the first base 1 and the second base 2 in the solid-state imaging device 10. Then each of the fourth base 4 and the fifth base 5 is disposed adjacently to the third base 3 serving as a center. Specifically, it is possible to uniformize and shorten a length of a current path between the protection element 300 of the third base 3 and a first signal processing circuit 200 of the fourth base 4 and a length of a current path between the protection element 300 and a storage circuit 500 of the fifth base 5.

This therefore allows the protection element 300 to efficiently absorb an overcurrent flowing to each of the first signal processing circuit 200 and the storage circuit 500, thus making it possible to provide a solid-state imaging device 10 with excellent protection performance against an overcurrent.

### Modification Example

FIG. 20 illustrates one example of a schematic plan configuration of a solid-state imaging device 10 according to a modification example of the third embodiment.

As illustrated in FIG. 20, two third bases 3 having a protection element 300 are respectively disposed at both end parts of a first base 1 and a second base 2 in an arrow Y direction. A fourth base 4 and a fifth base 5 are disposed adjacently to the two third bases 3 at a middle part, in an arrow Y direction, sandwiched by the two third bases 3.

The components other than the components described above are the same or substantially the same as the components of the solid-state imaging device 10 according to the third embodiment described above, and thus an overlapping description of the components will be omitted.

### [Workings and Effects]

With the solid-state imaging device 10 according to the modification example of the third embodiment, it is possible to provide workings and effects similar to the workings and effects provided by the solid-state imaging device 10 according to the third embodiment.

### 4. Fourth Embodiment

The solid-state imaging device 10 according to the fourth embodiment; of the present disclosure will be described with reference to FIG. 21.

### [Configuration of Solid-state Imaging Device 10]

FIG. 21 illustrates one example of a vertical cross-sectional configuration of main parts of the solid-state imaging device 10 according to the fourth embodiment. The solid-state imaging device 10 according to the fourth embodiment is obtained by changing the solid-state imaging device 10 according to the first embodiment to provide a structure of electrode extraction from a light incidence side (light-receiving surface side), which will be described in detail below,

As illustrated in FIG. 21, no second external terminal 623 and no through-wiring 621 are disposed on a support base 6 in the solid-state imaging device 10 according to the fourth embodiment. In the solid-state imaging device 10, a wire (bonding wire) 9W is electrically coupled to a first external terminal 115 disposed on the first base 1 on the side towards the arrow Z direction. The wire 9W is coupled to the first external terminal 115 through a wire opening (bonding opening) 8H disposed at a transparent substrate 8 and a protection film 7.

The components other than the components described above are the same or substantially the same as the components of the solid-state imaging device 10 according to the first embodiment described above, and thus an overlapping description of the components will be omitted.

### [Workings and Effects]

With the solid-state imaging device 10 according to the fourth embodiment, it is possible to provide workings and effects similar to the workings and effects provided by the solid-state imaging device 10 according to the first embodiment.

### 5. Fifth Embodiment

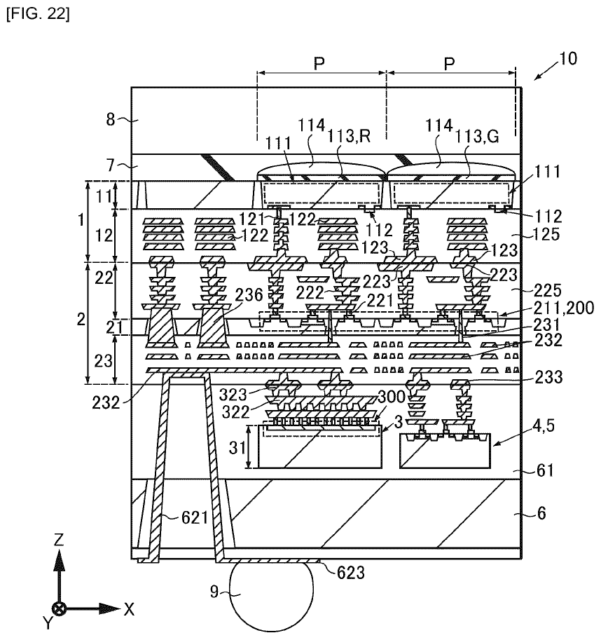

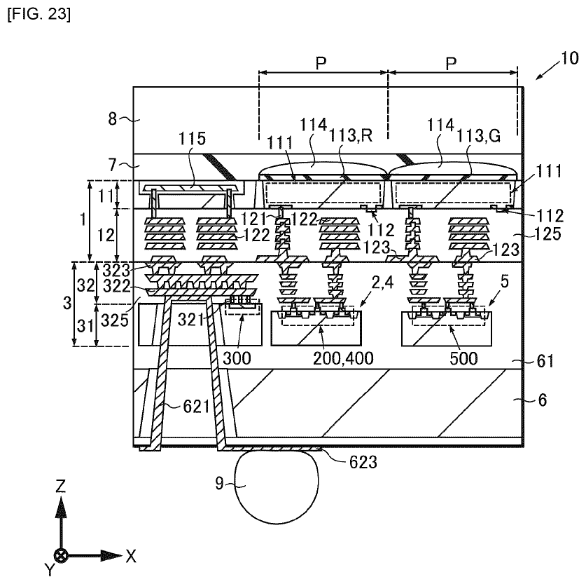

The solid-state imaging device 10 according to the fifth embodiment of the present disclosure will be described with reference to FIG. 22.

### [Configuration of Solid-state Imaging Device 10]

FIG. 22 illustrates one example of a vertical cross-sectional configuration of main parts of the solid-state imaging device 10 according to the fifth embodiment. The solid-state imaging device 10 according to the fifth embodiment is obtained by changing the structure of electrode extraction from the first base 1 in the solid-state imaging device 10 according to the first embodiment, which will be described in detail below.

As illustrated in FIG. 22, in the solid-state imaging device 10 according to the fifth embodiment, a second external terminal 623 disposed on a support base 6 is electrically coupled to a backside wiring layer 23 of a second base 2 through a through-wiring 621. The through-wiring 621 is disposed in a region different from a third base 3 having a protection element 300 and around a side surface of the third base 3. Wiring 232 of the backside wiring layer 23 electrically coupled to the through-wiring 621 is electrically coupled to the protection element 300.

Moreover, the backside wiring layer 23 is electrically coupled to a first wiring layer 12 of a first base 1 through each of a through-wiring 236 and a second wiring layer 22.

Here, the through-wiring 621 in the fifth embodiment corresponds to “a third through-wiring” according to the present technology. The through-wiring 236 corresponds to “a first through-wiring” according to the present technology.

Moreover, in the fifth embodiment, a fourth base 4 is stacked on the second base 2, but, instead of the fourth base 4, a fifth base 5 or another base may be stacked.

The components other than the components described above are the same or substantially the same as the components of the solid-state imaging device 10 according to the first embodiment described above, and thus an overlapping description of the components will be omitted.

### [Workings and Effects]

With the solid-state imaging device 10 according to the fifth embodiment, it is possible to provide workings and effects similar to the workings and effects provided by the solid-state imaging device 10 according to the first embodiment.

### 6. Sixth Embodiment

The solid-state imaging device 10 according to the sixth embodiment of the present disclosure will be described with reference to FIG. 23.

### [Configuration of Solid-state Imaging Device 10]

FIG. 23 illustrates one example of a vertical cross-sectional configuration of main parts of the solid-state imaging device 10 according to the sixth embodiment. The solid-state imaging device 10 according to the sixth embodiment is obtained by changing the stacking structure of the bases in the solid-state imaging device 10 according to the first embodiment to a two-layer structure, which will be described in detail below.

As illustrated in FIG. 23, the solid-state imaging device 10 according to the sixth embodiment is built by a two-layer structure that has, excluding a support base 6, a second base 2, a third base 3, and a fifth base 5 disposed at a lower layer on the side towards the support base 6 and has a first base 1 disposed at an upper layer.

Pixels P having the photoelectric conversion element 111 are disposed on the first base 1. A first signal processing circuit 200 and a second signal processing circuit 400 are disposed on the second base 2. In other words, instead of the second base 2, the fourth base 4 having the first signal processing circuit 200 and the second signal processing circuit 400 may be disposed.

A protection element 300 is disposed on the third base 3. Then a storage circuit 500 is disposed on the fifth base 5.

The components other than the components described above are the same or substantially the same as the components of the solid-state imaging device 10 according to the first embodiment described above, and an overlapping description of the components will be omitted.

### [Workings and Effects]

With the solid-state imaging device 10 according to the sixth embodiment, it is possible to provide workings and effects similar to the workings and effects provided by the solid-state imaging device 10 according to the first embodiment.

### 7. Seventh Embodiment

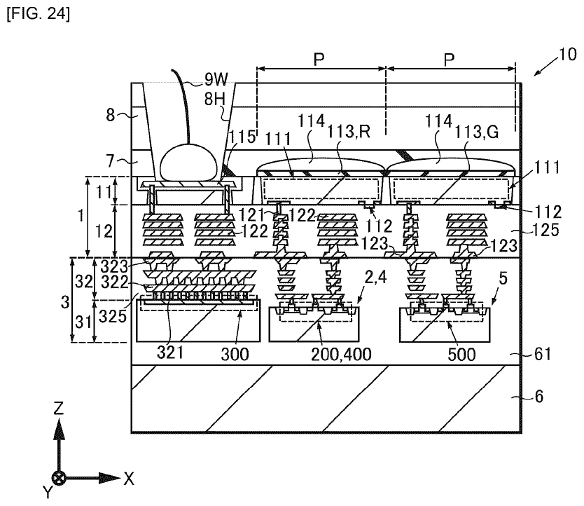

A solid-state imaging device 10 according to the seventh embodiment of the present disclosure will be described with reference to FIG. 24.

### [Configuration of Solid-state Imaging Device 10]

FIG. 24 illustrates one example of a vertical cross-sectional configuration of main parts of the solid-state imaging device 10 according to the seventh embodiment.

As illustrated in FIG. 24, the solid-state imaging device 10 according to the seventh embodiment is obtained by changing the stacking structure of the bases in the solid-state imaging device 10 according to the fourth embodiment to a two-layer structure, as is the case with the solid-state imaging device 10 according to the sixth embodiment.

The components other than the components described above are the same or substantially the same as the components of the solid-state imaging devices 10 according to the fourth embodiment and the sixth embodiment described above, and thus an overlapping description of the components will be omitted.

### [Workings and Effects]

With the solid-state imaging device 10 according to the seventh embodiment, it is possible to provide workings and effects similar to the workings and effects provided by the solid-state imaging devices 10 according to the fourth embodiment and the sixth embodiment.

### 8. Eighth Embodiment

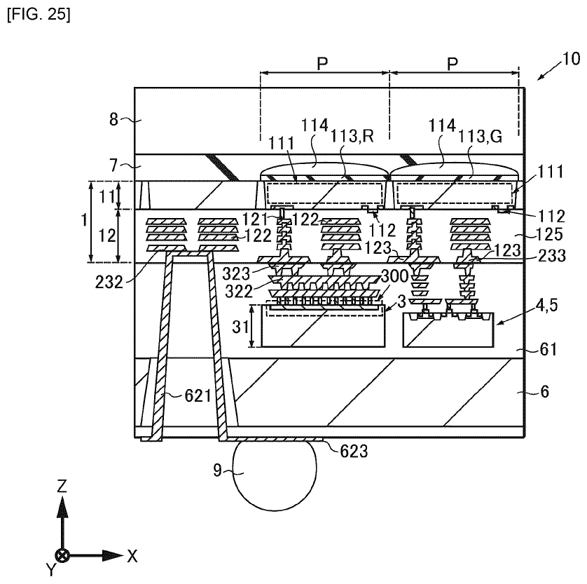

A solid-state imaging device 10 according to the eighth embodiment of the present disclosure will be described with reference to FIG. 25. [Configuration of Solid-state Imaging Device 10]

FIG. 25 illustrates one example of a vertical cross-sectional configuration of main parts of the solid-state imaging device 10 according to the eighth embodiment.

As illustrated in FIG. 25, the solid-state imaging device 10 according to the eighth embodiment is obtained by changing the stacking structure of the bases in the solid-state imaging devices 10 according to the fifth embodiment to a two-layer structure, as is the case with the solid-state imaging device 10 according to the sixth embodiment.

The components other than the components described above are the same or substantially the same as the components of the solid-state imaging devices 10 according to the fifth embodiment and according to the sixth embodiment, and thus an overlapping description of the components will be omitted.

### [Workings and Effects]

With the solid-state imaging device 10 according to the eighth embodiment, it is possible to provide workings and effects similar to the workings and effects provided by the solid-state imaging devices 10 according to the fifth embodiment and according to the sixth embodiment.

### 9. Example of Practical Application to Mobile Body

The technology according to an embodiment of the present disclosure (present technology) is applicable to various products. For example, the technology according to an embodiment of the present disclosure may be achieved in the form of an apparatus to be mounted to a mobile body of any kind. Non-limiting examples of the mobile body may include an automobile, an electric vehicle, a hybrid electric vehicle, a motorcycle, a bicycle, any personal mobility device, an airplane, an unmanned aerial vehicle (drone), a vessel, and a robot.

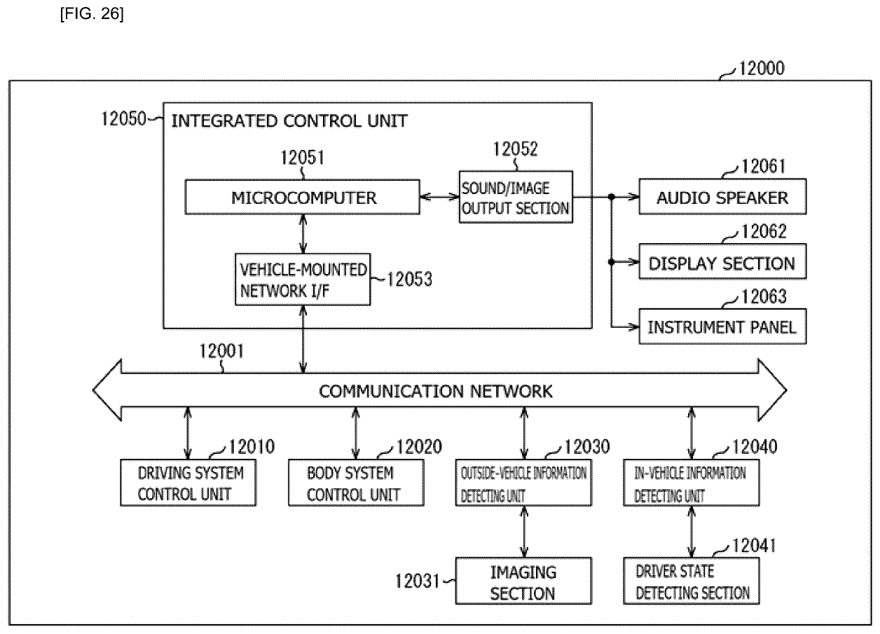

FIG. 26 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 26, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 26, an audio speaker 12061, a display section 12062, and an instrument panel 12063 are illustrated as the output device. The display section 12062 may, for example, include at least one of an on-board display and a head-up display.

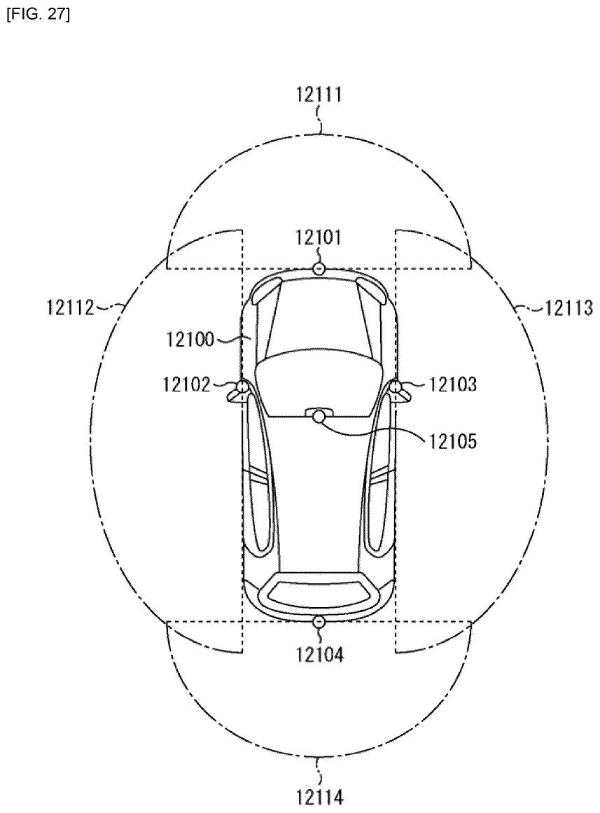

FIG. 27 is a diagram depicting an example of the installation position of the imaging section 12031.

In FIG. 27, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 27 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

The description has been given hereinabove of one example of the vehicle control system, to which the technology according to an embodiment of the present disclosure may be applied. The technology according to an embodiment of the present disclosure may be applied to the imaging section 12031 among components of the configuration described above. The application of the technology according to an embodiment of the present disclosure to the imaging section 12031 makes it possible to improve the number of bases, for manufacture of the imaging section 12031, that are obtainable from a wafer.

### 10. Example of Practical Application to Endoscopic Surgery System

The technology according to an embodiment of the present disclosure (present technology) is applicable to various products. For example, the technology according to an embodiment of the present disclosure may be applied to an endoscopic surgery system.

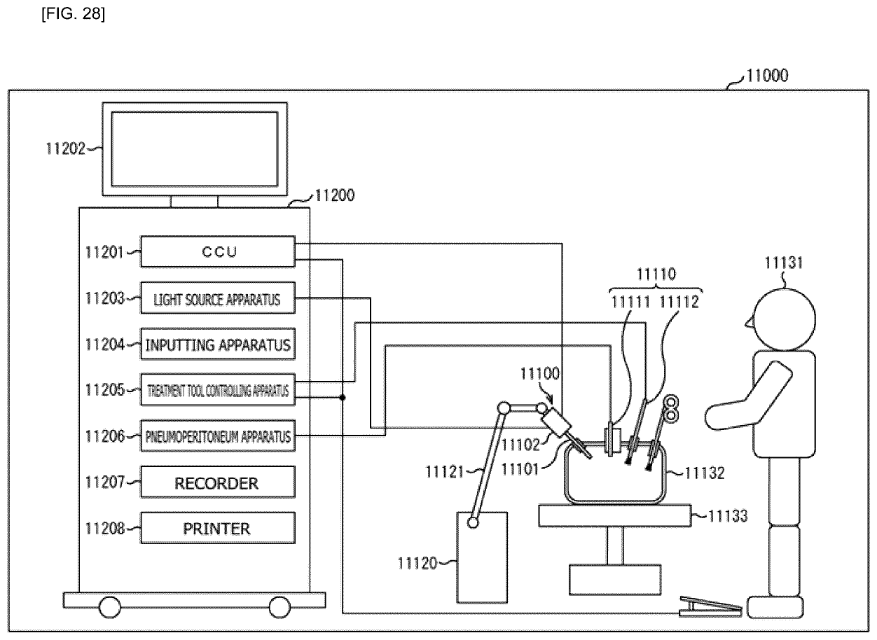

FIG. 28 is a view depicting an example of a schematic configuration of an endoscopic surgery system to which the technology according to an embodiment of the present disclosure (present technology) can be applied.

In FIG. 28, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

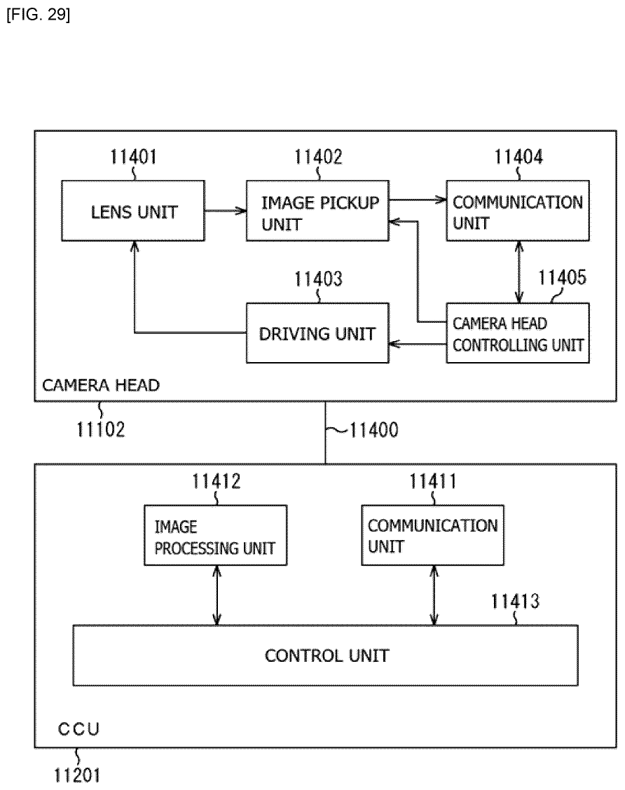

FIG. 29 is a block diagram depicting an example of a functional configuration of the camera head 11102 and the CCU 11201 depicted in FIG. 28.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like. The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

The description has been given above of one example of the endoscopic surgery system, to which the technology according to an embodiment of the present disclosure is applicable. The technology according to an embodiment of the present disclosure is applicable to, for example, the image pickup unit 11402 of the camera head 11102. Specifically, a base including a dedicated protection element to be shared by a plurality of bases is incorporated in the image pickup unit 10402. Applying the technology according to an embodiment of the present disclosure to the image pickup unit 10402 makes it possible to improve the number of bases, for manufacture of the image pickup unit 10402, that are obtainable from a wafer.

It is to be noted that although the endoscopic surgery system has been described as an example here, the technology according to an embodiment of the present disclosure may also be applied to, for example, a microscopic surgery system, and the like.

### 11. Other Embodiments

The present technology is not limited to the embodiments described above, and various modifications may be made without departing from the gist of the present technology.

For example, the solid-state imaging devices according to two or more embodiments, among the solid-state imaging devices according to the foregoing first to eighth embodiments, may be combined.

The solid-state imaging device 10 according to the first embodiment of the present disclosure includes the first base, the second base, and the third base.

The first base has the photoelectric conversion element that converts light into electric charge. The second base has the first signal processing circuit that performs signal processing on the basis of the electric charge obtained by the conversion performed by the photoelectric conversion element. The second base is different from the first base. The third base has the protection element that is electrically coupled to the first signal processing circuit and absorbs an overcurrent. The third base is different from the first base and the second base.

Thus, no protection element is specifically required for the semiconductor wafers respectively forming the first base and the second base. That is, it is possible to increase the number of first bases that are obtainable from the semiconductor wafer or the number of second bases that are obtainable from the semiconductor wafer.

The solid-state imaging device according to the second embodiment of the present disclosure has each of the second base 2 and the third base 3, which are included in the solid-state imaging device according to the first embodiment, stacked on the first base 1.

With the solid-state imaging device configured in the aforementioned manner, it is possible to achieve downsizing.

The solid-state imaging device according to the third embodiment of the present disclosure has the protection element, which is included in the first embodiment or the second embodiment, including the diode.

Therefore, it is possible to provide a solid-state imaging device with excellent protection performance against an overcurrent.

### Configuration of Present Technology

The present technology includes the following configurations. With the present technology having the following configurations, it is possible to improve the number of bases that are obtainable from the wafer while improving protection characteristics against an overcurrent in the solid-state imaging device.

(1)

A solid-state imaging device including:
a first base including a photoelectric conversion element that converts light into electric charge;
a second base including a first signal processing circuit that performs signal processing on a basis of the electric charge obtained through conversion performed by the photoelectric conversion element, the second base being different from the first base; and
a third base including a protection element that is electrically coupled to the first signal processing circuit and absorbs an overcurrent, the third base being different from the first base and the second base.
   (2)

The solid-state imaging device according to (1), in which each of the second base and the third base is stacked on the first base.

(3)

The solid-state imaging device according to (2), in which
the second base is stacked on the first base, and
the third base is stacked on a region of the first base different from the second base.
   (4)

The solid-state imaging device according to (2), in which the third base is stacked on the first base with the second base in between.

(5)

The solid-state imaging device according to any one of (1) to (4), in which
the first base includes, on a side opposite to a light incidence side, a first wiring layer including a first terminal,
the second base includes, on a side towards the first base, a second wiring layer including a second terminal, and
the first terminal and the second terminal are bonded in a face-to-face manner.
   (6)

The solid-state imaging device according to (5), in which
each of the first terminal and the second terminal is formed by Cu, and
the first terminal and the second terminal are bonded through Cu—Cu bonding.
   (7)

The solid-state imaging device according to any one of (1) to (3), in which
the first base includes, on a side opposite to a light incidence side, a first wiring layer including a first terminal,
the third base includes, on a side towards the first base, a third wiring layer including a third terminal, and
the first terminal and the third terminal are bonded in a face-to-face manner.
   (8)

The solid-state imaging device according to (7), in which
each of the first terminal and the third terminal is formed by Cu, and
the first terminal and the third terminal are bonded through Cu—Cu bonding.
   (9)

The solid-state imaging device according to any one of (1) to (3), further including a first external terminal disposed on the first base on a light incidence side, in which
the protection element is electrically coupled to the first external terminal through a first through-wiring penetrating the second base in a thickness direction.
   (10)

The solid-state imaging device according to any one of (4) to (6), further including a second external terminal disposed on the third base on a side opposite to the first base, in which
the protection element is electrically coupled to the second external terminal through a second through-wiring penetrating the third base in a thickness direction.
   (11)

The solid-state imaging device according to any one of (4) to (6), further including a second external terminal disposed on the third base on a side opposite to the first base, in which
the protection element is electrically coupled to the second external terminal through a third through-wiring which is disposed around the third base and which is electrically coupled to a first wiring layer of the first base.
   (12)

The solid-state imaging device according to (7), in which the protection element is electrically coupled to the first wiring layer through a first through-wiring penetrating the second base in a thickness direction.

(13)

The solid-state imaging device according to any one of (1) to (12), in which the protection element includes a diode.

(14)

The solid-state imaging device according to any one of (1) to (13), in which the protection element includes one or more selected from a capacitor, a resistor, and a coil.

(15)

The solid-state imaging device according to (7) or (8), in which
the third wiring layer includes: at least, an electrode disposed at the protection element; wiring disposed on the electrode on a side opposite to the protection element; and the third terminal disposed on the wiring on the side opposite to the protection element, and
when viewed in a thickness direction of the third base, the electrode has a plane area greater than a plane area of a coupling hole between the third terminal and the wiring.
   (16)

The solid-state imaging device according to (15), in which the electrode is formed into a plate-like shape.

(17)

The solid-state imaging device according to any one of (1) to (16), further including a fourth base including a second signal processing circuit that performs signal processing on a basis of the electric charge obtained through conversion performed by the photoelectric conversion element or signal processing on a basis of an output signal from the first signal processing circuit, the fourth base being different from the first base, the second base, and the third base.

(18)

The solid-state imaging device according to any one of (1) to (17), further including a fifth base including a storage circuit that stores an output signal from the first signal processing circuit, the fifth base being different from the first base, the second base, and the third base.

(19)

The solid-state imaging device according to (9), further including a wire electrically coupled to the first external terminal.

(20)

The solid-state imaging device according to (11), further including a bump electrode electrically coupled to the second external terminal.

The present application claims the benefit of Japanese Priority Patent Application JP2023-010910 filed with the Japan Patent Office on Jan. 27, 2023, the entire contents of which are incorporated herein by reference.

It should be understood by those skilled in the art that various modifications, combinations, sub-combinations and alterations may occur depending on design requirements and other factors insofar as they are within the scope of the appended claims or the equivalents thereof.

1. A solid-state imaging device comprising:
a first base including a photoelectric conversion element that converts light into electric charge;
a second base including a first signal processing circuit that performs signal processing on a basis of the electric charge obtained through conversion performed by the photoelectric conversion element, the second base being different from the first base; and
a third base including a protection element that is electrically coupled to the first signal processing circuit and absorbs an overcurrent, the third base being different from the first base and the second base.

2. The solid-state imaging device according to claim 1, wherein each of the second base and the third base is stacked on the first base.

3. The solid-state imaging device according to claim 2, wherein
the second base is stacked on the first base, and
the third base is stacked on a region of the first base different from the second base.

4. The solid-state imaging device according to claim 2, wherein the third base is stacked on the first base with the second base in between.

5. The solid-state imaging device according to claim 1, wherein
the first base includes, on a side opposite to a light incidence side, a first wiring layer including a first terminal,
the second base includes, on a side towards the first base, a second wiring layer including a second terminal, and
the first terminal and the second terminal are bonded in a face-to-face manner.

6. The solid-state imaging device according to claim 5, wherein
each of the first terminal and the second terminal is formed by Cu, and
the first terminal and the second terminal are bonded through Cu—Cu bonding.

7. The solid-state imaging device according to claim 1, wherein
the first base includes, on a side opposite to a light incidence side, a first wiring layer including a first terminal,
the third base includes, on a side towards the first base, a third wiring layer including a third terminal, and
the first terminal and the third terminal are bonded in a face-to-face manner.

8. The solid-state imaging device according to claim 7, wherein
each of the first terminal and the third terminal is formed by Cu, and
the first terminal and the third terminal are bonded through Cu—Cu bonding.

9. The solid-state imaging device according to claim 1, further comprising a first external terminal disposed on the first base on a light incidence side, wherein
the protection element is electrically coupled to the first external terminal through a first through-wiring penetrating the second base in a thickness direction.

10. The solid-state imaging device according to claim 4, further comprising a second external terminal disposed on the third base on a side opposite to the first base, wherein
the protection element is electrically coupled to the second external terminal through a second through-wiring penetrating the third base in a thickness direction.

11. The solid-state imaging device according to claim 4, further comprising a second external terminal disposed on the third base on a side opposite to the first base, wherein
the protection element is electrically coupled to the second external terminal through a third through-wiring which is disposed around the third base and which is electrically coupled to a first wiring layer of the first base.

12. The solid-state imaging device according to claim 7, wherein the protection element is electrically coupled to the first wiring layer through a first through-wiring penetrating the second base in a thickness direction.

13. The solid-state imaging device according to claim 1, wherein the protection element includes a diode.

14. The solid-state imaging device according to claim 1, wherein the protection element includes one or more selected from a capacitor, a resistor, and a coil.

15. The solid-state imaging device according to claim 7, wherein
the third wiring layer includes: at least, an electrode disposed at the protection element; wiring disposed on the electrode on a side opposite to the protection element; and the third terminal disposed on the wiring on the side opposite to the protection element, and
when viewed in a thickness direction of the third base, the electrode has a plane area greater than a plane area of a coupling hole between the third terminal and the wiring.

16. The solid-state imaging device according to claim 15, wherein the electrode is formed into a plate-like shape.

17. The solid-state imaging device according to claim 1, further comprising a fourth base including a second signal processing circuit that performs signal processing on a basis of the electric charge obtained through conversion performed by the photoelectric conversion element or signal processing on a basis of an output signal from the first signal processing circuit, the fourth base being different from the first base, the second base, and the third base.

18. The solid-state imaging device according to claim 1, further comprising a fifth base including a storage circuit that stores an output signal from the first signal processing circuit, the fifth base being different from the first base, the second base, and the third base.

19. The solid-state imaging device according to claim 9, further comprising a wire electrically coupled to the first external terminal.

20. The solid-state imaging device according to claim 11, further comprising a bump electrode electrically coupled to the second external terminal.
